(19) United States
(12) Patent Application Publication
(10) Pub. No.: US 2011/0252293 A1
(43) Pub. Date: Oct. 13, 2011

(54) Concatenated Coding Architecture for G.hnem PHY

(75) Inventors: Badri N. Varadarajan, Dallas, TX (US); Anand G. Dabak, Plano, TX (US); Il Han Kim, Dallas, TX (US)

(73) Assignee: TEXAS INSTRUMENTS INCORPORATED, Dallas, TX (US)

(21) Appl. No.: 13/084,348

(22) Filed: Apr. 11, 2011

Related U.S. Application Data
(60) Provisional application No. 61/323,124, filed on Apr. 12, 2010.

(51) Int. Cl. H03M 13/15; G06F 11/10

(52) U.S. Cl. 714/784; 714/752; 714/E11.032

(57) ABSTRACT

Embodiments provide a method for determining the number of parity bytes that are added by a Reed-Solomon encoder. The number of parity bytes are equivalent to the error correcting capability of the Reed-Solomon code. The number of parity bytes is based on the payload length or the information block size used in the Reed-Solomon encoder. Other factors may also be used to make this choice.

### CROSS-REFERENCE TO RELATED APPLICATIONS

This application claims the benefit of the filing dates of U.S. Provisional Application No. 61/323,124, which is titled “Concatenated Coding Architecture for G.hnem PHY” and was filed Apr. 12, 2010, the disclosure of which is hereby incorporated by reference herein in its entirety.

### TECHNICAL FIELD

Embodiments are directed, in general, to communication systems and, more specifically, coding architecture using a block code, such as, for example, a Reed-Solomon code.

### BACKGROUND

Forward error correction (FEC) or channel coding provides error control for data transmissions. To provide FEC, a transmitter adds redundant data to messages before the messages are sent. If selected properly, the redundant data allows a receiver to detect and correct a limited number of errors in the messages. The receiver should be able to use the redundant data to detect errors occurring anywhere in the message and to correct the errors without requiring the sender to provide additional data or resend the message. Because the message size increases with the addition of the redundant data, the use of FEC requires a higher bandwidth for the forward channel.

The maximum number of errors or missing bits that can be corrected with channel coding is determined by the design of the FEC code. Forward error correction uses a predetermined algorithm to calculate and add redundant bits to the message. The redundant bits are generated by applying a complex function to groups of the original message bits. There are two main categories of FEC codes: block codes and convolutional codes. Block codes operate on fixed-size blocks of bits or symbols of predetermined size. Convolutional codes work on bit or symbol streams of arbitrary length. Block codes and convolutional codes are often combined in concatenated coding schemes in which an “inner” convolutional code is combined with an “outer” block code.

The G.hnem standards body aims to define specifications for low-frequency, narrowband powerline communication using orthogonal frequency division multiplexing (OFDM) techniques. The forward error correction scheme to be used is of particular interest. Two techniques were considered: low-density parity check codes (LDPC) based on the broadband G.hn spec, and a concatenation of outer Reed-Solomon code with inner convolutional code.

Reed-Solomon (RS) and low-density parity-check (LDPC) are examples of block codes in use today. RS codes are block codes that add t check symbols to the data. An RS code can detect up to t erroneous symbols and can correct up to t/2 symbols. Reed-Solomon codes are widely used in data storage and transmission technologies. Low-density parity-check (LDPC) codes are a class of efficient linear block codes. LDPC coding provides performance close to the channel capacity. LDPC codes are now used in many communication standards, such as G.hn/G.9960 (the ITU-T Standard for networking over power lines, phone lines and coaxial cable).

### SUMMARY

A proposed concatenated coding architecture is described herein. More specifically, the error-correcting capability of an outer Reed-Solomon code may be chosen based on the length of the payload packet. For smaller block lengths, the Reed-Solomon code is chosen to correct fewer errors. In an extreme case, for example with payload lengths smaller than 20 bytes, the Reed-Solomon code does not add value and should not be used.

In one embodiment, an error correction encoding circuit comprises a circuit adapted to divide protocol data units into information blocks of a selected block length. The protocol data units comprise a payload having a payload length. A Reed-Solomon encoder circuit is adapted to sequentially receive the information blocks. The Reed-Solomon encoder circuit appends a number of parity-check bytes to each of the information blocks. The number of parity-check bytes is selected based upon the payload or information block length. The selected block length may be K bytes, and the number of parity-check bytes is R bytes. The encoder circuit outputs Reed-Solomon encoded blocks of length N=K+R bytes. If the payload or information block length is P bytes, then the value of P is used to select the number of parity-check bytes R. When the payload or information block length is below a minimum length, then no parity-check bytes are added to the information blocks. The extra bytes do not provide value to the system when the information block size is small. A plurality of distinct payload length ranges may be defined. A different number of parity-check bytes may be added to the payload or information blocks for each distinct payload length range. A convolutional encoder circuit may be coupled to the output of the Reed-Solomon encoder circuit to form a concatenated encoder.

### BRIEF DESCRIPTION OF THE DRAWINGS

Having thus described the invention in general terms, reference will now be made to the accompanying drawings, wherein:

FIG. 1 is a block diagram of a FEC encoder consisting of an outer Reed-Solomon (RS) encoder and an inner convolutional encoder;

FIG. 2 illustrates a PHY frame format that is processed by a FEC encoder;

FIG. 3 illustrates simulation results for an 8-byte payload that has been encoded using concatenated coding and using LDPC coding;

FIG. 4 illustrates simulation results for a 21-byte payload that has been encoded using concatenated coding and using LDPC coding;

FIG. 5 illustrates simulation results for a 50-byte payload that has been encoded using concatenated coding and using LDPC coding;

FIG. 6 illustrates simulation results for a 100-byte payload that has been encoded using concatenated coding and using LDPC coding; and

FIG. 7 is a flowchart illustrating one method for performing concatenated encoding.

### DETAILED DESCRIPTION

The invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention.

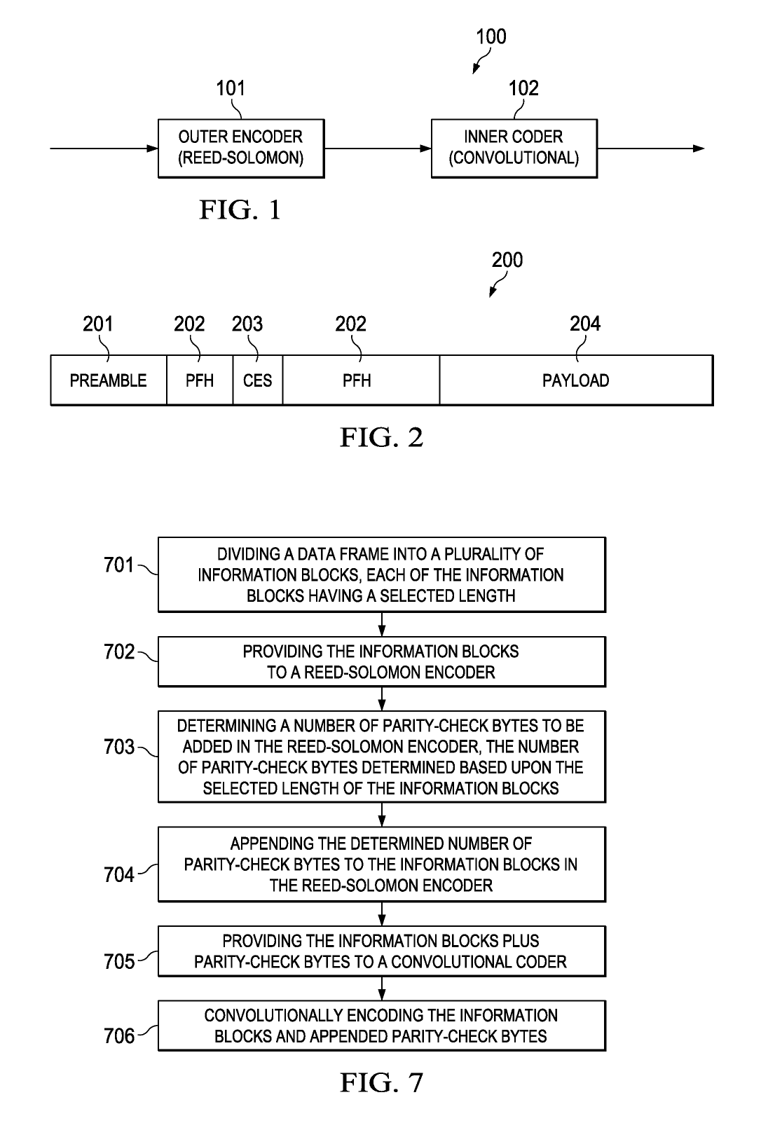

FIG. 1 is a block diagram of a FEC encoder 100 consisting of an outer Reed-Solomon (RS) encoder 101 and an inner convolutional encoder 102. Outer encoder 101 receives incoming RS information blocks comprising a number of bytes K. Outer encoder 101 then adds a number of RS parity-check bytes R to each information block. The output of the outer encoder 101 consists of RS-encoded blocks, each having (K+R) bytes. The RS-encoded blocks are the input to inner encoder 102. Inner encoder 102 receives a number of incoming bits k_{I} and uses an inner convolutional code (CC) rate r_{I} to generate a number of output FEC codewords of bits N_{FEC}. The FEC codeword size depends on the overall code rate.

In one embodiment, FEC encoder 100 may operate on a PHY frame 200 having a format illustrated in FIG. 2. Frame 200 comprises preamble 201, PHY header 202, channel estimation signals (CES) 203, and payload 204. Preamble 201 and CES 203 do not carry data, but are used for synchronization and initial channel estimation. The PHY header identifies the frame type and carries other data, such as the RS codeword size and the CC rate, and may be spread among one or more segments 202. Payload 204 comprises blocks of data from the medium access control (MAC) referred to as MAC protocol data units (MPDU). Incoming MPDUs are mapped onto the PHY payload 203 for each frame 200. The length of the payload 203 may vary for each frame 200 and, in some frames, may have zero length.

All of the data in frame 200, including the header and payload, may be processed by the FEC encoder all at once, or the header data and payload data may be encoded separately. In one embodiment, the MPDU data in payload 204 encoded separately from the header data. The payload is divided into a number (m) of RS information blocks each having size K. The RS information blocks are input to the outer encoder 101 (FIG. 1), which generates m encoded RS blocks, each having N=K+R bytes. A systems using this type of encoding will be able to correct up to t=R/2 error bytes in the encoded RS blocks.

The RS encoded blocks output from outer encoder 101 are converted to a bit stream and are then formed into inner input blocks having k_{I}=8×(K+R) bits. The inner blocks are input to convolutional encoder 102 Inner convolutional encoder 102 has a code rate of r_{I} and a constraint length, L. The FEC codewords output from inner coder 102 have a length N_{FEC}=k_{I}/r_{I} bits. This output code length corresponds to N_{FEC}=8×(K+R)/r_{I}. The output of the FEC encoder 100 may be further processed, such as by interleaving, etc., before being transmitted.

In other embodiments, LDPC encoding may be used in place of the concatenated coder 100. Simulation results comparing LDPC with concatenated codes for various payload block lengths (i.e. 8, 21, 50 and 100 bytes blocks) are discussed below. The LDPC code in the G.hn standard has the same generating matrix structure as Wimax, so a Wimax simulator may be adapted to analyze the input block lengths under consideration. Since the LDPC code is not defined for 8 bytes, a 12-byte code was used instead to represent small payloads. Under these assumptions, performance results for various input block lengths are tested over an additive white Gaussian noise (AWGN) channel model.

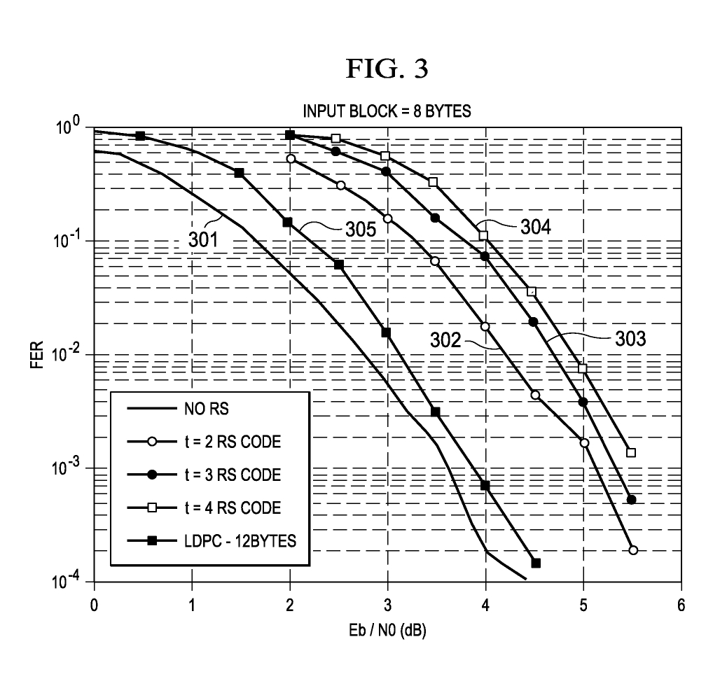

FIG. 3 illustrates the simulation results for an 8-byte payload that has been encoded using concatenated coding with no RS-encoding (301) and with RS-encoding for t=2, 3, 4 (302-303) and using LDPC coding (305). As illustrated in FIG. 3, the concatenated code without RS coding (301) was better than LDPC (305) by approximately 0.3 dB at frame error rate (FER)=1 %. A 12-byte LDPC was used in the simulation shown in FIG. 3 since 8-byte LDPC is not defined. These results suggest using concatenated coding with no RS coding or using t=2 RS coding.

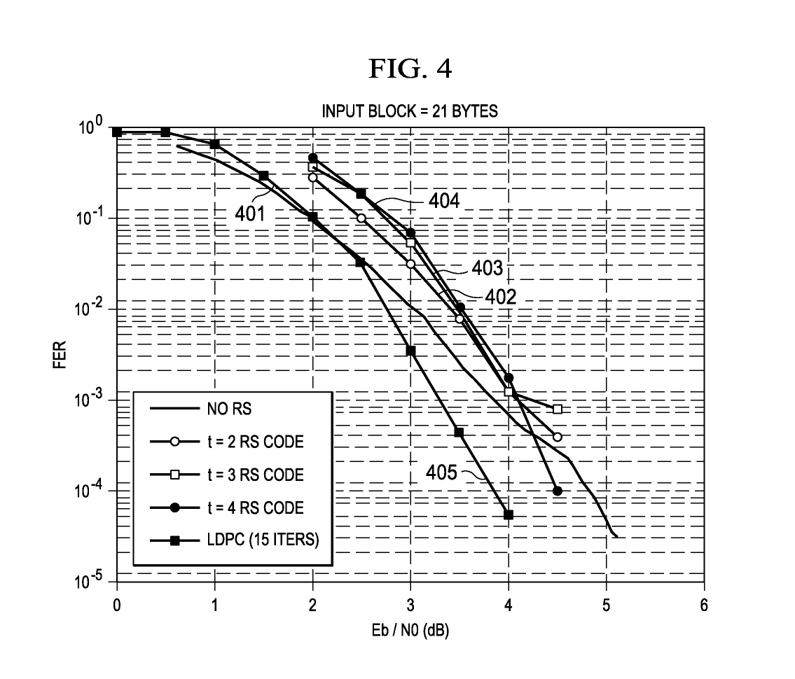

FIG. 4 illustrates the simulation results for a 21-byte payload that has been encoded using concatenated coding with no RS-encoding (401) and with RS-encoding for t=2, 3, 4 (402-403) and using 15 iterations of LDPC coding (405). As illustrated in FIG. 4, at 1% FER, concatenated coding was worse than LDPC by 0.2-0.6 dB depending on the type of RS coding used. These results suggest using concatenated coding with no RS coding or using t=2 RS coding.

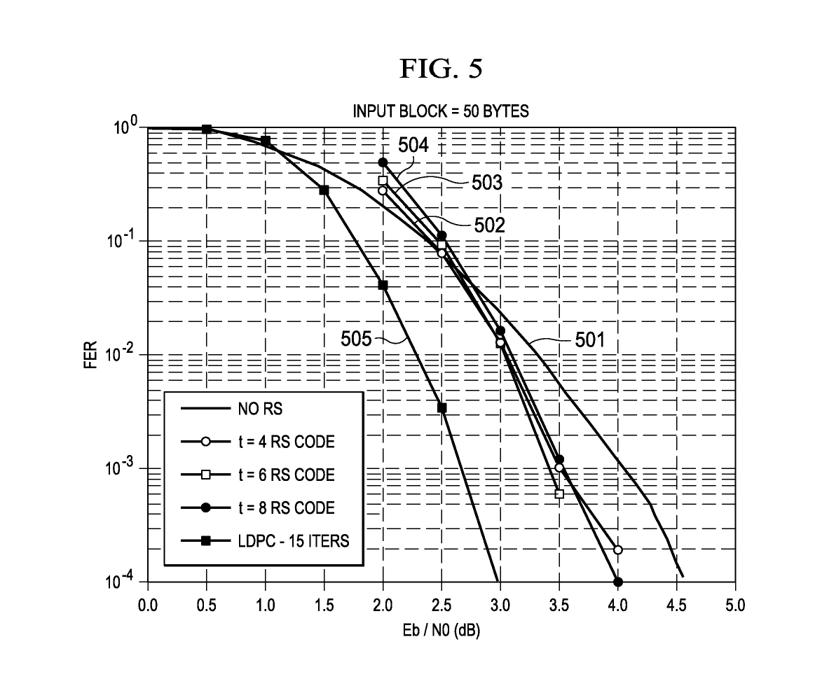

FIG. 5 illustrates the simulation results for a 50-byte payload that has been encoded using concatenated coding with no RS-encoding (501) and with RS-encoding for t=4, 6, 8 (502-503) and using 15 iterations of LDPC coding (505). As illustrated in FIG. 5, at 1% FER, concatenated coding with RS coding was worse than LDPC by about 0.7 dB while concatenated coding without RS was worse than LDPC by 1 db. These results suggest using concatenated coding with t=4 RS coding.

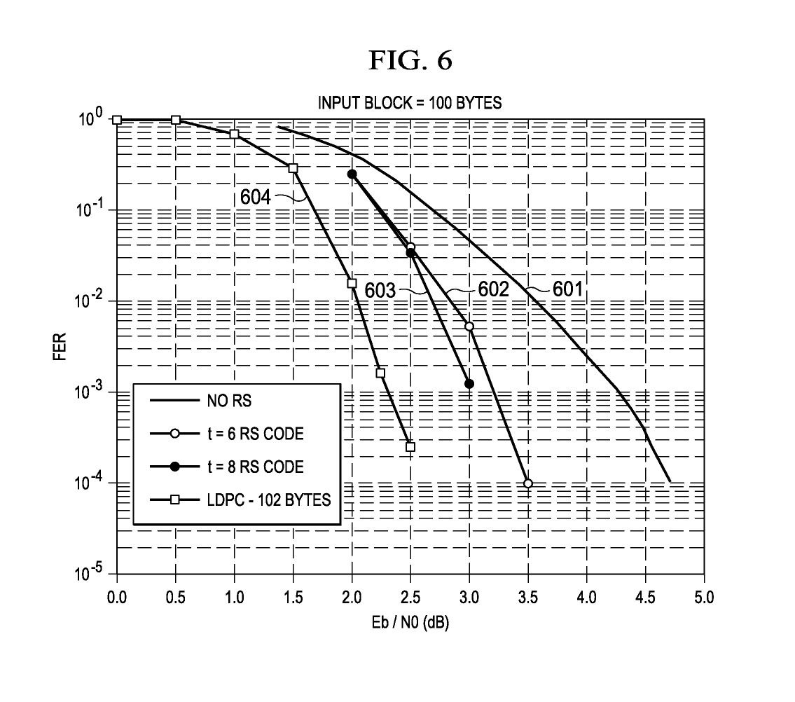

FIG. 6 illustrates the simulation results for a 100-byte payload that has been encoded using concatenated coding with no RS-encoding (601) and with RS-encoding for t=6 or 8 (602, 603) and using LDPC coding on a 102 bytes block (604). As illustrated in FIG. 6, at 1% FER, concatenated coding with RS coding was worse than LDPC by about 0.6-0.7 dB while concatenated coding without RS was worse than LDPC by 1.5 db. These results suggest using concatenated coding with t=8 RS coding.

TABLE 1 summarizes the performance results illustrated in FIGS. 3-6. For small block lengths, LDPC suffers a 0.35 dB loss with respect to a convolutional code. For larger block lengths, LDPC offers at most 0.7 dB better performance than concatenated coding. This results illustrated in FIGS. 3-6 assume 15 iterations of LDPC. With fewer iterations, the advantage shown for LDPC would be even smaller.

TABLE 1

| | Number | | |
|---|---|---|---|
| | of errors | SNR | |
| | corrected | required by | SNR |
| | by RS for | concatenated | required |
| Payload | optimum | code to | by LDPC |
| Length | performance | achieve | to achieve |
| (bytes) | in AWGN | 1% FER | 1% FER |
| 8 | 0 | 2.75 | 3.1 |
| 21 | 0/2 | 3.0/3.4 | 2.75 |
| 50 | 4 | 3.0 | 2.3 |
| 100 | 8 | 2.7 | 2.1 |

In one embodiment, the RS coder for the concatenated encoder is selected based upon the size of the payload to be encoded. For small payloads and small block lengths, the RS coding is chosen to correct fewer errors. For very small payloads, no RS coding is used because it does not add any value to the system. Alternatively, as the payload blocks increase, the RS coding should be selected to correct more errors. This process for selecting RS coding differs from the typical method employed in encoding systems, which use a fixed RS coding rate without regard to the payload or block size.

TABLE 2 identifies the number of errors corrected by the RS coder and the number of parity bits to be added based upon the block size of the payload according to one embodiment.

TABLE 2

| RS information | Inner | RS |
|---|---|---|
| block size: | code rate: | parity check: |
| K bytes | r_{I} | R = 2 t bytes |
| ≦16-25 | 1/2, 2/3 | 0 |
| 25-50 | 1/2, 2/3 | 4 |
| 50-75 | 1/2, 2/3 | 8 |
| 75-100 | 1/2, 2/3 | 12 |
| 100-239 | 1/2, 2/3 | 16 |

It will be understood that different numbers of parity bits may be added in other embodiments and will consistent with the findings disclosed herein as long as the number of parity bits varies by block size.

FIG. 7 is a flowchart illustrating one method for performing the concatenated encoding described herein. In step 701, a data frame is divided into a plurality of information blocks. The data frame may be a payload carrying data in a communication system, for example. The payload may be of varying size depending upon the type of information being carried or depending on other factors. The information blocks each have the same selected length. In step 702, the information blocks are provided to a Reed-Solomon encoder. In step 703, the system determines a number of parity-check bytes to be added to the information blocks in the Reed-Solomon encoder. The number of parity-check bytes is determined based upon the selected length of the information blocks. More specifically, the longer the information block size, the more parity-check bytes will be added to by the Reed-Solomon encoder. In step 704, the number of parity-check bytes determined in step 703 are appended to the information blocks. In step 705, the information blocks with the parity bytes appended are provided to a convolutional encoder, which convolutionally encodes the information blocks and parity-check bytes. The encoded data may then be further processed and transmitted or stored.

Many modifications and other embodiments of the invention will come to mind to one skilled in the art to which this invention pertains having the benefit of the teachings presented in the foregoing descriptions, and the associated drawings. Therefore, it is to be understood that the invention is not to be limited to the specific embodiments disclosed. Although specific terms are employed herein, they are used in a generic and descriptive sense only and not for purposes of limitation.

What is claimed is:

1. An error correction encoding circuit, comprising:
a circuit adapted to divide a data frame into information blocks of a selected block length, the data frame comprising a payload having a payload length;
a forward error correction encoder circuit adapted to sequentially receive the information blocks, the encoder circuit appending a number of parity-check elements to each of the information blocks, the number of parity-check elements selected based upon the payload length.

2. The error correction encoding circuit of claim 1, wherein the forward error correction encoder circuit comprises a Reed-Solomon encoder.

3. The error correction encoding circuit of claim 2, wherein the selected block length is K bytes and the number of parity-check bytes is R, and wherein the encoder circuit outputs Reed-Solomon encoded blocks of length N=K+R.

4. The error correction encoding circuit of claim 3, wherein the payload length is P bytes and wherein the value of P is used to select the number of parity-check bytes R.

5. The error correction encoding circuit of claim 1, wherein no parity-check bytes are added to the information blocks when the payload length is below a minimum length.

6. The error correction encoding circuit of claim 1, wherein a plurality of distinct payload length ranges are defined, and wherein a different number of parity-check bytes are added to the information blocks for each distinct payload length range.

7. The error correction encoding circuit of claim 1, further comprising:
a convolutional encoder circuit coupled to the output of the Reed-Solomon encoder circuit.

8. A method for providing error correction data, comprising:
dividing a data frame into information blocks of a selected block length;
providing the information blocks to a forward error correction encoder;
appending, in the forward error correction encoder, a number of parity-check bytes to each of the information blocks, the number of parity-check bytes selected based upon a payload length corresponding to the data frame.

9. The method of claim 8, wherein the forward error correction encoder comprises a Reed-Solomon encoder.

10. The method for providing error correction data of claim 9, further comprising:
providing the output of the Reed-Solomon encoder to a convolutional encoder.

11. The method for providing error correction data of claim 9, wherein the selected block length is K bytes and the number of parity-check bytes is R, and wherein the encoder circuit outputs Reed-Solomon encoded blocks of length N=K+R.

12. The method for providing error correction data of claim 11, wherein the data frame is a payload of length P bytes and wherein the value of P is used to select the number of parity-check bytes R.

13. The method for providing error correction data of claim 8, wherein no parity-check bytes are added to the information blocks when the payload length is below a minimum length.

14. The method for providing error correction data of claim 8, wherein a plurality of distinct payload length ranges are defined and wherein a different number of parity-check bytes are added to the information blocks for each distinct payload length range.

15. A computer-readable storage medium comprising instructions for providing forward error correction coding, wherein the instructions, when executed, cause a processor to perform actions comprising:
dividing a data frame into information blocks of a selected block length;
providing the information blocks to a forward error correction encoder;
appending, in the forward error correction encoder, a number of parity-check bytes to each of the information blocks, the number of parity-check bytes selected based upon a payload length corresponding to the data frame.

16. The computer-readable storage medium of claim 15, wherein the forward error correction encoder comprises a Reed-Solomon encoder.

17. The computer-readable storage medium of claim 16, wherein the selected block length is K bytes and the number of parity-check bytes is R, and wherein the encoder circuit outputs Reed-Solomon encoded blocks of length N=K+R.

18. The computer-readable storage medium of claim 15, wherein the data frame is a payload of length P bytes, and wherein the value of P is used to select the number of parity-check bytes R.

19. The computer-readable storage medium of claim 15, wherein no parity-check bytes are added to the information blocks when the payload length is below a minimum length.

20. The computer-readable storage medium of claim 15, wherein a plurality of distinct payload length ranges are defined and wherein a different number of parity-check bytes are added to the information blocks for each distinct payload length range.
